(19) United States
(12) Patent Application Publication
(10) Pub. No.: US 2025/0280661 A1
(43) Pub. Date: Sep. 4, 2025

(54) DISPLAY PANEL, DISPLAY APPARATUS, AND METHOD FOR MANUFACTURING DISPLAY PANEL

(71) Applicants: Hefei Visionox Technology Co., Ltd., Hefei (CN); Visionox Technology Inc., Suzhou (CN)

(72) Inventors: Yuting FU, Hefei (CN); Cheng-Yi LIN, Hefei (CN); Cheng-Chu TSENG, Hefei (CN); Jui-Yang TSAI, Hefei (CN); Hsiang-Yin HOU, Hefei (CN); Wei-Ju HUANG, Hefei (CN); Yi-Yu LAI, Hefei (CN); Yuan YAO, Hefei (CN); Shizhen FENG, Hefei (CN)

(73) Assignees: Hefei Visionox Technology Co., Ltd., Hefei (CN); Visionox Technology Inc., Suzhou (CN)

(21) Appl. No.: 18/750,257

(22) Filed: Jun. 21, 2024

(30) Foreign Application Priority Data
Feb. 29, 2024 (CN) 202410232931.8

(51) Int. Cl. H10K 59/122; H10K 59/12; H10K 59/35

(52) U.S. Cl. CPC H10K 59/122; H10K 59/1201; H10K 59/353

(57) ABSTRACT

A display panel, a display apparatus, and a method for manufacturing a display panel. The display panel includes a base plate, a plurality of isolation structures, and a light-emitting layer. A first layer and a second layer are arranged to form the isolation structure, and the orthographic projection of the first layer arranged close to the base plate on the base plate is located within the orthographic projection of the second layer on the base plate.

### CROSS REFERENCE TO RELATED APPLICATION

The present application claims priority to Chinese Patent Application No. 202410232931.8 filed on Feb. 29, 2024, which is incorporated herein by reference in its entirety.

### TECHNICAL FIELD

The present application relates to the field of display technology, and particularly to a display panel, a display apparatus, and a method for manufacturing a display panel.

### BACKGROUND

Planar display apparatus based on Organic Light Emitting Diode (OLED) and Light Emitting Diode (LED), etc., are widely used in cell phones, TVs, notebook computers, desktop computers and other consumer electronic products due to their high image quality, power saving, thin body and wide range of applications, and have become the mainstream of the display apparatus.

However, the usability of the current OLED display products needs to be improved.

### SUMMARY

Embodiments of the present application provide a display panel, a display apparatus, and a method for manufacturing a display panel, aiming to improve the usability of the display panel.

Some embodiments of a first aspect of the present application provide a display panel, including: a base plate; a plurality of isolation structures located on the base plate, the isolation structure including a first layer and a second layer located at a side of the first layer away from the base plate, an orthographic projection of the first layer on the base plate being located within an orthographic projection of the second layer on the base plate; a plurality of isolation openings encircled by the isolation structures; and a light-emitting layer located on the base plate and including light-emitting units located in the isolation openings; in which a distance between an edge of the orthographic projection of the first layer on the base plate close to the light-emitting unit and an edge of the orthographic projection of the second layer on the base plate close to the light-emitting unit is an extension distance, and in at least two of the light-emitting units, the extension distance of the isolation structure close to one of the two light-emitting units is greater than the extension distance of the isolation structure close to the other one of the two light-emitting units.

Some embodiments of a second aspect of the present application provide a display panel, including: a base plate; a plurality of isolation structures located on the base plate, the isolation structure including a first layer and a second layer located at a side of the first layer away from the base plate, an orthographic projection of the first layer on the base plate being located within an orthographic projection of the second layer on the base plate; a plurality of isolation openings encircled by the isolation structures; and a light-emitting layer located on the base plate and including light-emitting units located in the isolation openings; in which the first layer includes a top surface at a side away from the base plate, the second layer includes a bottom surface at a side close to the base plate, the top surface and the bottom surface are in contact, a distance between an edge of an orthographic projection of the top surface on the base plate close to the light-emitting unit and an edge of an orthographic projection of the bottom surface on the base plate close to the light-emitting unit is an extension distance, and in at least two of the light-emitting units, the extension distance of the isolation structure close to one of the two light-emitting units is greater than the extension distance of the isolation structure close to the other one of the two light-emitting units, wherein the extension distances close to the light-emitting units of a same color are same; and the extension distances close to the light-emitting units of different colors are different.

Some embodiments of a third aspect of the present application provide a display panel, including: a base plate; a plurality of isolation structures located on the base plate, the isolation structure including a first layer and a second layer located at a side of the first layer away from the base plate, an orthographic projection of the first layer on the base plate being located within an orthographic projection of the second layer on the base plate; a plurality of isolation openings encircled by the isolation structures; and a light-emitting layer located on the base plate and including light-emitting units located in the isolation openings; in which a distance between orthographic projections of the first layers located at two sides of a same isolation opening on the base plate is a sixth distance, and in at least two of the light-emitting units, the sixth distance of the isolation structure close to one of the two light-emitting units is greater than the sixth distance of the isolation structure close to the other one of the two light-emitting units.

Some embodiments of a fourth aspect of the present application provide a display apparatus, including the display panel according to any of the above implementations.

Some embodiments of a fifth aspect of the present application provide a method for manufacturing a display panel, including: preparing a plurality of isolation structures on a base plate, a first isolation opening and a second isolation opening encircled by the isolation structures, the isolation structure including a first layer and a second layer located at a side of the first layer away from the base plate, an orthographic projection of the first layer on the base plate being located within an orthographic projection of the second layer on the base plate, a distance between an edge of the orthographic projection of the first layer on the base plate close to a light-emitting unit and an edge of the orthographic projection of the second layer on the base plate close to the light-emitting unit being an extension distance; preparing a first light-emitting material layer and a first electrode material layer on the base plate and patterning the first light-emitting material layer and the first electrode material layer to form a first light-emitting unit and a first sub-electrode located in the first isolation opening, the extension distance including a first distance close to the first light-emitting unit; and preparing a second light-emitting material layer and a second electrode material layer on the base plate and patterning the second light-emitting material layer and the second electrode material layer to form a second light-emitting unit and a second sub-electrode located in the second isolation opening, the extension distance including a second distance close to the second light-emitting unit, and the second distance being greater than the first distance.

The display panel according to the embodiments of the present application includes the base plate, the isolation structures, and the light-emitting layer. The first layer and the second layer are arranged to form the isolation structure, the orthographic projection of the first layer arranged close to the base plate on the base plate is located within the orthographic projection of the second layer on the base plate, the area of the second layer is greater than the area of the first layer, the second layer covers a surface of the first layer close to the second layer, and in such cases, the first layer is recessed with respect to the second layer in a direction away from the isolation opening. When the light-emitting layer is prepared, the light-emitting layer has a large drop at the edge of the isolation structure, and the first layer is concave with respect to the second layer, it's difficult for the light-emitting layer to be connected at the edge of the isolation structure, and thus fracture occurs and the light-emitting layer is fractured, resulting in the light-emitting units that are spaced apart from each other. In this way, the crosstalk of carriers within the light-emitting layer is reduced, the display effect of the display panel is improved, and the light-emitting units can be prepared without a precision mask plate, so as to reduce the development and use of the precision mask plate and reduce the preparation cost.

### BRIEF DESCRIPTION OF THE DRAWINGS

Other features, objects and advantages of the present application will be more apparent from reading the following detailed description of non-limiting embodiments with reference to the accompanying drawings, in which the same or similar reference numerals denote the same or similar features, and the accompanying drawings are not drawn to actual scale.

FIG. 1 shows a partial sectional view of a display panel according to an embodiment of the present application;

FIG. 2 shows a partial sectional view of a display panel in another embodiment;

FIG. 3 shows a partial sectional view of a display panel in yet another embodiment;

FIG. 4 shows a partial top view of a display panel according to an embodiment of the present application;

FIG. 5 shows a partial sectional view of a display panel in yet another embodiment;

FIG. 6 shows a partial sectional view of a display panel in yet another embodiment;

FIG. 7 shows a partial sectional view of a display panel in yet another embodiment;

FIG. 8 shows a partial sectional view of a display panel in yet another embodiment;

FIG. 9 shows a partial sectional view of a display panel in yet another embodiment;

FIG. 10 shows a partial sectional view of a display panel in yet another embodiment;

FIG. 11 shows a partial top view of a display panel in yet another embodiment;

FIG. 12 shows a schematic flow chart of a method for manufacturing a display panel according to an embodiment of the present application;

FIGS. 13 to 16 show diagrams of a process for manufacturing a display panel according to an embodiment of the present application.

### REFERENCE NUMERALS

10, display panel;
100, base plate;
200, isolation structure; 210, first layer; 211, top surface; 220, second layer; 221, bottom surface; 230, third layer; 240, isolation opening; 241, first isolation opening; 242, second isolation opening; 243, third isolation opening;
300, light-emitting layer; 310, light-emitting unit; 311, first light-emitting unit; 312, second light-emitting unit; 313, third light-emitting unit;
400, first electrode layer; 410, first electrode; 411, first sub-electrode; 412, second sub-electrode; 413, third sub-electrode;
500, pixel defining layer; 510, pixel defining portion; 520, pixel opening; 530, pixel electrode;
D0, extension distance; D1, first distance; D2, second distance; D3, third distance; D4, fourth distance; D5, fifth distance; D6, sixth distance; D7, seventh distance; D8, eighth distance; D9, ninth distance.

### DETAILED DESCRIPTION

Features and exemplary embodiments of various aspects of the present application will be described in detail below. In order to make the objectives, technical solutions, and advantages of the present application clearer, the present application will be further described in detail below with reference to the drawings and specific embodiments. It should be understood that the specific embodiments described herein are merely configured to explain the present application, rather than to limit the present application. For those skilled in the art, the present application can be implemented without some of these specific details. The following description of the embodiments is merely to provide a better understanding of the present application by illustrating the examples of the present application.

It should be noted that, in the present application, relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device comprising/including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes the elements.

It should be understood that when describing the structure of a component, if a layer/area is referred to as being “on” or “above” another layer/region, it may mean that the layer/area is directly on the other layer/region or that other layers/regions may be included between the layer/area and the other layer/area. Moreover, if the component is turned over, the layer/region will be “below” or “under” the other layer/region.

The embodiments of the present application provide a display panel, a display apparatus, and a method for manufacturing a display panel, and various embodiments of the display panel, the display apparatus, and the method for manufacturing a display panel will be described below in conjunction with the accompanying drawings.

The embodiments of the present application provide a display panel which may be an Organic Light Emitting Diode (OLED) display panel.

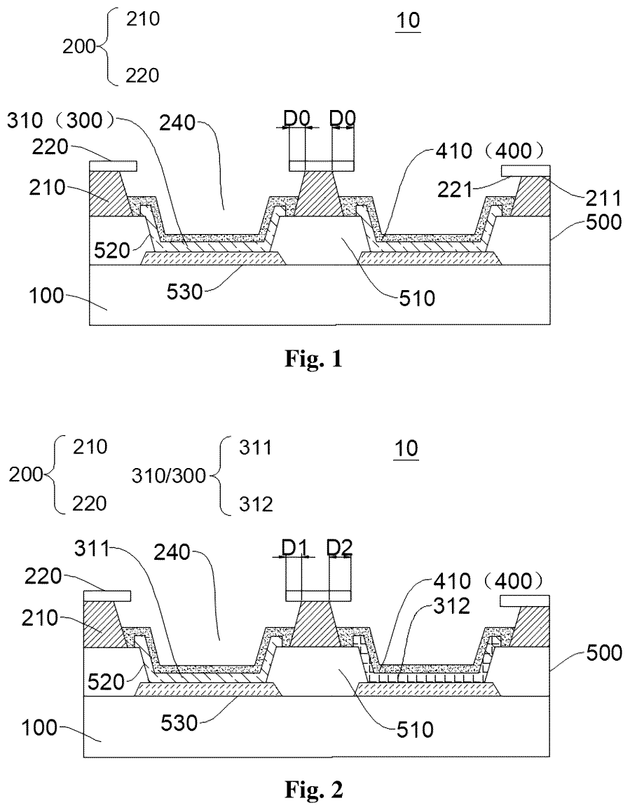

Reference is made to FIG. 1, which shows a partial sectional view of a display panel according to an embodiment of the present application.

As shown in FIG. 1, the embodiments of the first aspect of the present application provide a display panel 10, including: a base plate 100; a plurality of isolation structures 200 located on the base plate 100, the isolation structures 200 encircling a plurality of isolation openings 240, the isolation structure 200 including a first layer 210 and a second layer 220 located at a side of the first layer 210 away from the base plate 100, an orthographic projection of the first layer 210 on the base plate 100 being located within an orthographic projection of the second layer 220 on the base plate 100; and a light-emitting layer 300 located on the base plate 100 and including light-emitting units 310 located in the isolation openings 240; in which a distance between an edge of the orthographic projection of the first layer 210 on the base plate 100 close to the light-emitting unit 310 and an edge of the orthographic projection of the second layer 220 on the base plate 100 close to the light-emitting unit 310 is an extension distance DO, and in at least two of the light-emitting units 310, the extension distance D0 of the isolation structure 200 close to one of the two light-emitting units 310 is greater than the extension distance D0 of the isolation structure 200 close to the other one of the two light-emitting units 310.

The display panel 10 according to the embodiments of the present application includes the base plate 100, the isolation structures 200, and the light-emitting layer 300. The first layer 210 and the second layer 220 are arranged to form the isolation structure 200, the orthographic projection of the first layer 210 arranged close to the base plate 100 on the base plate 100 is located within the orthographic projection of the second layer 220 on the base plate 100, the area of the second layer 220 is greater than the area of the first layer 210, the second layer 200 covers a surface of the first layer 210 close to the second layer 220, and in such cases, the first layer 210 is recessed with respect to the second layer 220 in a direction away from the isolation opening 240. When the light-emitting layer 300 is prepared, the light-emitting layer 300 has a large drop at the edge of the isolation structure 200, and the first layer 210 is concave with respect to the second layer 220, it's difficult for the light-emitting layer 300 to be connected at the edge of the isolation structure 200, and thus fracture occurs and the light-emitting layer 300 is fractured, resulting in the light-emitting units 310 that are spaced apart from each other. In this way, the crosstalk of carriers within the light-emitting layer 300 is reduced, the display effect of the display panel 10 is improved, and the light-emitting units 310 can be prepared without a precision mask plate, so as to reduce the development and use of the precision mask plate and reduce the preparation cost. For example, the light-emitting units 310 include a blue light-emitting unit, a green light-emitting unit, and a red light-emitting unit, the extension distance D0 of the isolation structure 200 close to the blue light-emitting unit is greater than the extension distance D0 of the isolation structure 200 close to the green light-emitting unit, and the extension distance D0 of the isolation structure 200 close to the green light-emitting unit is greater than the extension distance D0 of the isolation structure 200 close to the red light-emitting unit, and thus it may be determined that the red light-emitting unit is prepared first, followed by the green light-emitting unit, and finally the blue light-emitting unit.

The extension distance D0 of the isolation structure 200 close to the light-emitting unit 310 refers to a distance between an edge of the first layer 210 of the isolation structure 200, which is located at the periphery of the light-emitting unit 310 and surrounding the light-emitting unit 310, close to the light-emitting unit 310 and an edge of a contact surface between the second layer 220 and the first layer 210 close to the light-emitting unit 310.

The base plate 100 may be arranged in various ways. For example, the base plate 100 may include a substrate and an array base plate arranged on the substrate. Alternatively, the base plate 100 is the substrate. Alternatively, the base plate 100 includes a buffer layer, a support plate, and the like at a side away from the base plate.

Related solutions of the isolation structure are described in patent applications No. PCT/CN2023/134518, No. 202310759370.2, No. 202311117143.6, No. 202311499823.9, No. 202310707209.0, No. 202311346196.5, No. 202310692671.8, and No. 202310909421.5, the contents of which are incorporated herein by reference and will not be repeated herein.

In some optional embodiments, the extension distances D0 close to the light-emitting units 310 of a same color are the same.

In these optional embodiments, the extension distances D0 of the isolation structures 200 located at the periphery of the light-emitting units 310 of a same color are the same, it may be determined that the light-emitting units 310 of a same color are prepared in a same step. Moreover, the extension distances D0 corresponding to the light-emitting units 310 of a same color are the same, and if the extension distances D0 corresponding to at least two light-emitting units 310 are different, the colors of lights emitted by the two light-emitting units 310 are different, and the two light-emitting units 310 are vapor deposited in different steps. Therefore, the extension distances D0 corresponding to the light-emitting units 310 of a same color being controlled to be the same facilitates determining the vapor deposition order for the light-emitting units 310 according to the extension distances D0 corresponding to the light-emitting units 310.

In some optional embodiments, the extension distances D0 close to the light-emitting units 310 of different colors are different.

In these optional embodiments, the extension distances D0 of the isolation structures 200 located at the periphery of the light-emitting units 310 of different colors are different, it may be determined that the light-emitting units 310 of different colors are prepared in different steps. The extension distances D0 corresponding to the light-emitting units 310 of a same color are the same, and the extension distances D0 corresponding to the light-emitting units 310 of different colors are different, therefore the vapor deposition order for the light-emitting units 310 can be determined according to the extension distances D0 corresponding to the light-emitting units 310.

As shown in FIG. 1, in some optional embodiments, the first layer 210 includes a top surface 211 at a side away from the base plate 100, the second layer 220 includes a bottom surface 221 at a side close to the base plate 100, the top surface 211 and the bottom surface 221 are in contact, a distance between an edge of an orthographic projection of the top surface 211 on the base plate 100 close to the light-emitting unit 310 and an edge of an orthographic projection of the bottom surface 221 on the base plate 100 close to the light-emitting unit 310 is the extension distance DO.

In these optional embodiments, in the preparation process, the isolation structures 200 may be wet etched in a wet etching process when the light-emitting units 310 of different colors are prepared, i.e., the first layers 210 of the isolation structures 200 may be etched. Therefore, in order to reflect the difference in the etching of the first layers 210, the distance between the edge of the orthographic projection of the top surface 211 on the base plate 100 close to the light-emitting unit 310 and the edge of the orthographic projection of the bottom surface 221 on the base plate 100 close to the light-emitting unit 310 is used as the extension distance DO, so as to determine the vapor deposition order for the light-emitting units 310 according to the extension distances D0 corresponding to the light-emitting units 310.

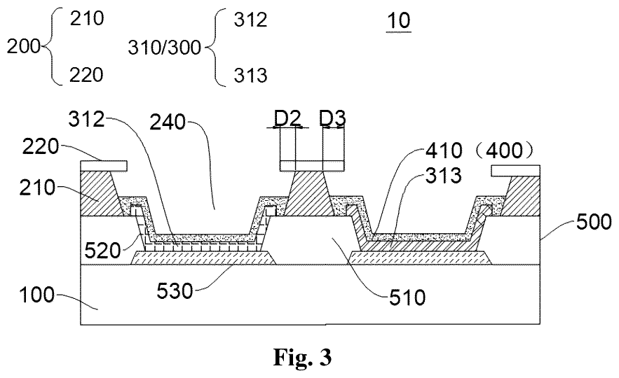

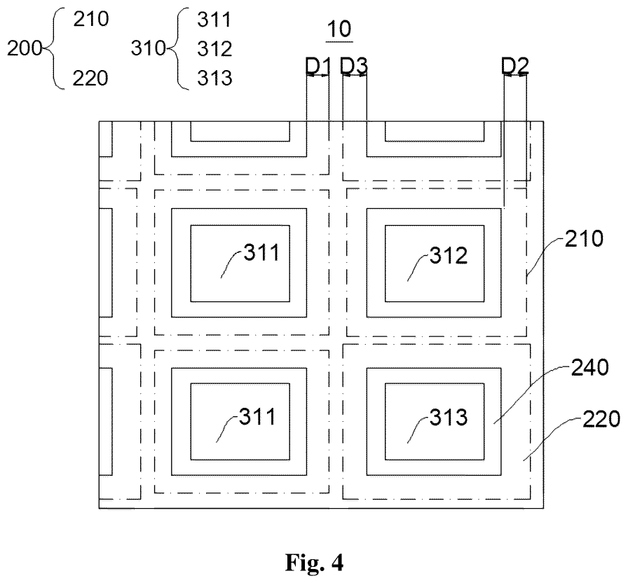

Reference is made to FIGS. 2 to 4, in which FIG. 2 shows a partial sectional view of a display panel in another embodiment, FIG. 3 shows a partial sectional view of a display panel in yet another embodiment, and FIG. 4 shows a partial top view of a display panel according to an embodiment of the present application.

As shown in FIGS. 2 to 4, in some optional embodiments, the light-emitting units 310 include a first light-emitting unit 311, a second light-emitting unit 312, and a third light-emitting unit 313 of different colors, the extension distance D0 of the isolation structure 200 close to the first light-emitting unit 311 is a first distance D1, the extension distance D0 of the isolation structure 200 close to the second light-emitting unit 312 is a second distance D2, the extension distance D0 of the isolation structure 200 close to the third light-emitting unit 313 is a third distance D3, and at least two of the first distance D1, the second distance D2, and the third distance D3 are different.

In these optional embodiments, at least two of the first distance D1, the second distance D2, and the third distance D3 are different, i.e., the extension distances DO corresponding to at least two of the first light-emitting unit 311, the second light-emitting unit 312, and the third light-emitting unit 313 are different, and the vapor deposition order for the light-emitting units may be determined according to the different extension distances DO. For example, the third distance D3 is greater than the second distance D2, i.e., the extension distance D0 of the isolation structure 200 close to the third light-emitting unit 313 is greater than the extension distance D0 of the isolation structure 200 close to the second light-emitting unit 312, it may be determined that the second light-emitting unit 312 is prepared first, followed by the third light-emitting unit 313; the second distance D2 is greater than the first distance D1, i.e., the extension distance D0 of the isolation structure 200 close to the second light-emitting unit 312 is greater than the extension distance D0 of the isolation structure 200 close to the first light-emitting unit 311, it may be determined that the first light-emitting unit 311 is prepared first, followed by the second light-emitting unit 312.

Optionally, the first light-emitting unit 311 is a light-emitting unit emitting red light, the second light-emitting unit 312 is a light-emitting unit emitting green light, and the third light-emitting unit 313 is a light-emitting unit emitting blue light.

In some optional embodiments, the extension distance D0 is in a range of 0.1 μm to 1.5 μm.

In these optional embodiments, the extension distance D0 is greater than or equal to 0.1 μm to alleviate the following problem: the extension distance D0 is too small, and thus the concavity of the first layer 210 with respect to the second layer 220 is too less, it is difficult for the light-emitting layer 300 to be disconnected at the edge of the second layer 220, and the light-emitting layer 300 is likely to be in contact with the first layer 210 after being disconnected, causing crosstalk of carriers within the light-emitting layer 300. The extension distance D0 is less than or equal to 1.5 μm to alleviate the following problem: the extension distance D0 is too large, and thus the concavity of the first layer 210 with respect to the second layer 220 is too much, the first electrode 410 is deposited within the isolation opening 240 far away from the sidewall of the first layer 210, and it is difficult for the first electrode 410 to overlap the first layer 210, causing poor overlapping.

As shown in FIGS. 1 to 3, in some optional embodiments, the display panel 10 further includes a first electrode layer 400 located a side of the light-emitting layer 300 away from the base plate 100.

Optionally, the first electrode layer 400 includes a plurality of first electrodes 410 arranged at intervals, the first electrode 410 is electrically connected with the isolation structure 200.

In these optional embodiments, the isolation structures 200 separate the first electrode layer 400 to form the first electrodes 410 that are spaced apart from each other, and the first electrodes 410 are electrically connected through the isolation structures 200 to form a planar electrode, so as to ensure normal light emission of the light-emitting unit 310.

In some optional embodiments, an orthographic projection of the light-emitting unit 310 on the base plate 100 is located within an orthographic projection of the first electrode 410 on the base plate 100.

In these optional embodiments, the orthographic projection of the light-emitting unit 310 on the base plate 100 is located within the orthographic projection of the first electrode 410 on the base plate 100, i.e., the first electrode 410 is arranged covering the light-emitting unit 310 to be used as an electrode of the light emitting-unit 310, so as to ensure normal light emission of the light-emitting unit 310 and improve the display effect of the display panel 10.

Optionally, the light-emitting units 310 and the isolation structures 200 are arranged alternately, i.e., the light-emitting units 310 are spaced apart from each other, so as to reduce crosstalk of carriers and color crossing among the light-emitting units 310.

In some optional embodiments, the second layer 220 includes an electrically conductive material or an electrically insulating material.

In these optional embodiments, the second layer 220 includes an electrically conductive material, such as a non-metal electrically conductive material or a metal electrically conductive material. If the second layer 220 includes a non-metal electrically conductive material or an electrically insulating material, it is difficult to etch the second layer 220 during the wet etching of the first layer 210 using an etching solution, thereby making it easier to achieve the concavity of the first layer 210 with respect to the second layer 220.

In some optional embodiments, the second layer 220 includes a metal material, and the first layer 210 and the second layer 220 are of different materials.

In these optional embodiments, if both the first layer 210 and the second layer 220 include metal materials, the first layer 210 may be wet etched using an etching solution, and the etching rate of the second layer 220 may be less than the etching rate of the first layer 210 by selecting the etching solution. Since the etching rate of the first layer 210 is greater, when the first layer 210 is wet etched using the etching solution, even though the second layer 220 may be etched to some degree, the first layer 210 is etched faster, and thus the first layer 210 is concave with respect to the second layer 220.

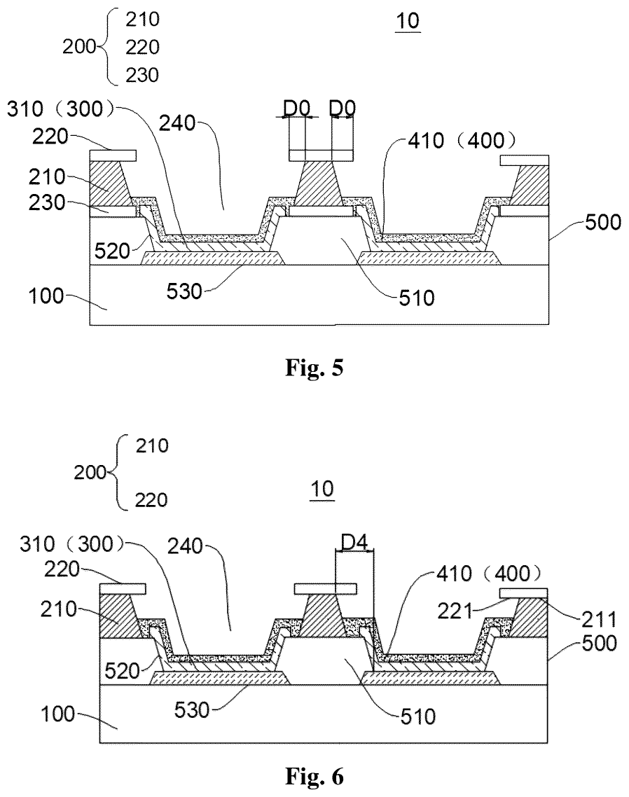

Reference is made to FIG. 5, which shows a partial sectional view of a display panel in yet another embodiment.

As shown in FIG. 5, in some optional embodiments, the isolation structure 200 further includes a third layer 230 located at a side of the first layer 210 towards the base plate 100, the orthographic projection of the first layer 210 on the base plate 100 is located within an orthographic projection of the third layer 230 on the base plate 100.

In these optional embodiments, in order to obtain the concave first layer 210, the first layer 210 has a greater etching rate than the second layer 220 and the third layer 230 during the etching, thereby forming the concave first layer 210. Due to the greater etching rate of the first layer 210, a great amount of waste materials produced by the etching are likely to get into other locations of the display panel 10, causing undesirable effects. After the third layer 230 being arranged, the first layer 210 can be better attached to the third layer 230, and the waste materials produced by the etching will fall on the third layer 230, which are easy to be cleaned up.

Optionally, the second layer 220 is made of titanium (Ti), the first layer 210 is made of aluminum (Al), and the third layer 230 is made of titanium (Ti) or molybdenum (Mo), i.e., the isolation structure 200 includes a triple-layer metal composite material such as Ti/Al/Ti (titanium/aluminum/titanium) or Ti/Al/Mo (titanium/aluminum/molybdenum).

In some optional embodiments, the display panel 10 further includes a pixel defining layer 500 located on the base plate 100, the pixel defining layer 500 includes a plurality of pixel defining portions 510 and a plurality of pixel openings 520 encircled by the pixel defining portions 510, the pixel opening 520 is communicated with the isolation opening 240.

In these optional embodiments, the pixel defining portions 510 encircle the pixel openings 520 to define the light-emitting area of the display panel 10. The pixel opening 520 is communicated with the isolation opening 240 to reduce the blocking of the pixel opening 520 by the isolation structure 200, so as to ensure the light emitting effect of the display panel 10.

In some optional embodiments, the isolation structure 200 is located at a side of the pixel defining portion 510 away from the base plate 100.

In these optional embodiments, the isolation structure 200 is arranged on the pixel defining portion 510 and has a large height drop with respect to the pixel opening 520. When the first electrode layer 400 is prepared, the first electrode layer 400 is more likely to be disconnected at the isolation structure 200 due to the large drop, reducing the difficulty for preparing the first electrode layer 400.

In some optional embodiments, the display panel 10 further includes a plurality of pixel electrodes 530 located at a side of the pixel defining portions 510 close to the base plate 100, an orthographic projection of the pixel electrode 530 on the base plate 100 at least partially overlaps an orthographic projection of the pixel opening 520 on the base plate 100.

In these optional embodiments, the orthographic projection of the pixel electrode 530 on the base plate 100 at least partially overlaps the orthographic projection of the pixel opening 520 on the base plate 100, i.e., at least a portion of the pixel electrode 530 is exposed from the pixel opening 520 to be used as an electrode of the light-emitting unit 310, so as to ensure the light emission of the light-emitting unit 310. One of the pixel electrode 530 and the first electrode 410 is used as the anode of the light-emitting unit 310, and the other one is used as the cathode of the light-emitting unit 310. In the embodiments of the present application, for example, the pixel electrode 530 is used as the anode of the light-emitting unit 310, and the first electrode 410 is used as the cathode of the light-emitting unit 310.

Optionally, an orthographic projection of the isolation structure 200 on the base plate 100 is located within an orthographic projection of the pixel defining portion 510 on the base plate 100, and the isolation structure 200 is located entirely on the pixel defining portion 510, so as to reduce the blocking of the pixel opening 520 by the isolation structure 200, thereby reducing the blocking of light emission of the light-emitting unit 310 by the isolation structure 200, and ensuring the light emitting effect of the light-emitting unit 310.

Reference is made to FIG. 6, which shows a partial sectional view of a display panel in yet another embodiment.

As shown in FIG. 6, optionally, a distance between the edge of the orthographic projection of the first layer 210 on the base plate 100 close to the light-emitting unit 310 and an edge of the orthographic projection of the pixel opening 520 on the base plate 100 is a fourth distance D4, and in at least two of the light-emitting units 310, the fourth distance D4 of the isolation structure 200 close to one of the two light-emitting units 310 is greater than the fourth distance D4 of the isolation structure 200 close to the other one of the two light-emitting units 310. For example, the light-emitting units 310 include a blue light-emitting unit, a green light-emitting unit, and a red light-emitting unit, the fourth distance D4 of the isolation structure 200 close to the blue light-emitting unit is greater than the fourth distance D4 of the isolation structure 200 close to the green light-emitting unit, and the fourth distance D4 of the isolation structure 200 close to the green light-emitting unit is greater than the fourth distance D4 of the isolation structure 200 close to the red light-emitting unit, and thus it may be determined that the red light-emitting unit is prepared first, followed by the green light-emitting unit, and finally the blue light-emitting unit.

Optionally, the fourth distances D4 close to the light-emitting units 310 of a same color are the same.

In these optional embodiments, the fourth distances D4 of the isolation structures 200 located at the periphery of the light-emitting units 310 of a same color are the same, it may be determined that the light-emitting units 310 of a same color are prepared in a same step. Moreover, the fourth distances D4 corresponding to the light-emitting units 310 of a same color are the same, and if the fourth distances D4 corresponding to at least two light-emitting units 310 are different, the colors of lights emitted by the two light-emitting units 310 are different, and the two light-emitting units 310 are vapor deposited in different steps. Therefore, the fourth distances D4 corresponding to the light-emitting units 310 of a same color being controlled to be the same facilitates determining the vapor deposition order for the light-emitting units 310 according to the fourth distances D4 corresponding to the light-emitting units 310.

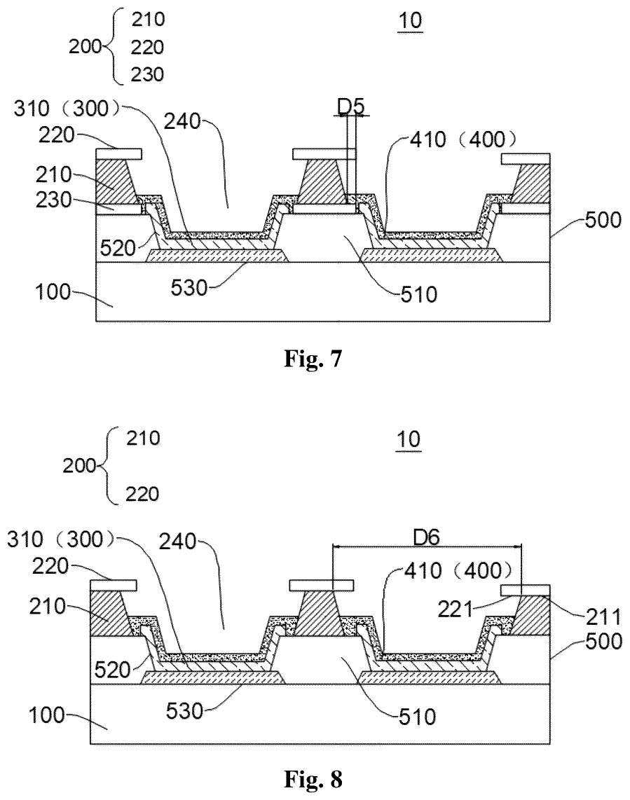

Reference is made to FIG. 7, which shows a partial sectional view of a display panel in yet another embodiment.

As shown in FIG. 7, optionally, a distance between an edge of the orthographic projection of the third layer 230 on the base plate 100 close to the light-emitting unit 310 and the edge of the orthographic projection of the second layer 220 on the base plate 100 close to the light-emitting unit 310 is a fifth distance D5, and in at least two of the light-emitting units 310, the fifth distance D5 of the isolation structure 200 close to one of the two light-emitting units 310 is greater than the fifth distance D5 of the isolation structure 200 close to the other one of the two light-emitting units 310. For example, the light-emitting units 310 include a blue light-emitting unit, a green light-emitting unit, and a red light-emitting unit, the fifth distance D5 of the isolation structure 200 close to the blue light-emitting unit is greater than the fifth distance D5 of the isolation structure 200 close to the green light-emitting unit, and the fifth distance D5 of the isolation structure 200 close to the green light-emitting unit is greater than the fifth distance D5 of the isolation structure 200 close to the red light-emitting unit, and thus it may be determined that the red light-emitting unit is prepared first, followed by the green light-emitting unit, and finally the blue light-emitting unit.

In some optional embodiments, the fifth distances D5 close to the light-emitting units 310 of a same color are the same.

In these optional embodiments, the fifth distances D5 of the isolation structures 200 located at the periphery of the light-emitting units 310 of a same color are the same, it may be determined that the light-emitting units 310 of a same color are prepared in a same step. Moreover, the fifth distances D5 corresponding to the light-emitting units 310 of a same color are the same, and if the fifth distances D5 corresponding to at least two light-emitting units 310 are different, the colors of lights emitted by the two light-emitting units 310 are different, and the two light-emitting units 310 are vapor deposited in different steps. Therefore, the fifth distances D5 corresponding to the light-emitting units 310 of a same color being controlled to be the same facilitates determining the vapor deposition order for the light-emitting units 310 according to the fifth distances D5 corresponding to the light-emitting units 310.

Optionally, the light-emitting layer 300 includes an electron injection layer (EIL), an electron transport layer (ETL), a light-emitting material layer, a hole injection layer (HIL), and a hole transport layer (HTL).

Reference is made to FIG. 1, the embodiments of the second aspect of the present application provide a display panel 10, including: a base plate 100, a plurality of isolation structures 200, and a light-emitting layer 300; the isolation structures 200 being located on the base plate 10, the isolation structures 200 encircling a plurality of isolation openings 240, the isolation structure 200 including a first layer 210 and a second layer 220 located at a side of the first layer 210 away from the base plate 100, an orthographic projection of the first layer 210 on the base plate 100 being located within an orthographic projection of the second layer 220 on the base plate 100; and the light-emitting layer 300 being located on the base plate 100 and including light-emitting units 310 located in the isolation openings 240; in which the first layer 210 includes a top surface 211 at a side away from the base plate 100, the second layer 220 includes a bottom surface 221 at a side close to the base plate 100, the top surface 211 and the bottom surface 221 are in contact, a distance between an edge of an orthographic projection of the top surface 211 on the base plate 100 close to the light-emitting unit 310 and an edge of an orthographic projection of the bottom surface 221 on the base plate 100 close to the light-emitting unit 310 is an extension distance DO, and in at least two of the light-emitting units 310, the extension distance D0 of the isolation structure 200 close to one of the two light-emitting units 310 is greater than the extension distance D0 of the isolation structure 200 close to the other one of the two light-emitting units 310.

The display panel 10 according to the embodiments of the present application includes the base plate 100, the isolation structures 200, and the light-emitting layer 300. The first layer 210 and the second layer 220 are arranged to form the isolation structure 200, the orthographic projection of the first layer 210 arranged close to the base plate 100 on the base plate 100 is located within the orthographic projection of the second layer 220 on the base plate 100, the area of the second layer 220 is greater than the area of the first layer 210, the second layer 200 covers a surface of the first layer 210 close to the second layer 220, and in such cases, the first layer 210 is recessed with respect to the second layer 220 in a direction away from the isolation opening 240. When the light-emitting layer 300 is prepared, the light-emitting layer 300 has a large drop at the edge of the isolation structure 200, and the first layer 210 is concave with respect to the second layer 220, it's difficult for the light-emitting layer 300 to be connected at the edge of the isolation structure 200, and thus fracture occurs and the light-emitting layer 300 is fractured, resulting in the light-emitting units 310 that are spaced apart from each other. In this way, the crosstalk of carriers within the light-emitting layer 300 is reduced, the display effect of the display panel 10 is improved, and the light-emitting units 310 can be prepared without a precision mask plate, so as to reduce the development and use of the precision mask plate and reduce the preparation cost. In at least two of the light-emitting units 310, the extension distances D0 of the isolation structure 200 close to the two light-emitting units 310 are different, and the vapor deposition order for the two light-emitting units 310 may be determined according to the different extension distances D0 corresponding to the two light-emitting units 310, i.e., according to the individual design of the isolation structure 200, so as to obtain a display panel 10 in which the vapor deposition order for the light-emitting units 310 can be determined. In the preparation process, the isolation structures 200 may be wet etched in a wet etching process when the light-emitting units 310 of different colors are prepared, i.e., the first layers 210 of the isolation structures 200 may be etched. Therefore, in order to reflect the difference in the etching of the first layers 210, the distance between the edge of the orthographic projection of the top surface 211 on the base plate 100 close to the light-emitting unit 310 and the edge of the orthographic projection of the bottom surface 221 on the base plate 100 close to the light-emitting unit 310 is used as the extension distance DO, so as to determine the vapor deposition order for the light-emitting units 310 according to the extension distances DO corresponding to the light-emitting units 310.

Reference is made to FIG. 8, which shows a partial sectional view of a display panel in yet another embodiment.

As shown in FIG. 8, the embodiments of the third aspect of the present application provide a display panel 10, including: a base plate 100; a plurality of isolation structures 200 located on the base plate 100, the isolation structures 200 encircling a plurality of isolation openings 240, the isolation structure 200 including a first layer 210 and a second layer 220 located at a side of the first layer 210 away from the base plate 100, an orthographic projection of the first layer 210 on the base plate 100 being located within an orthographic projection of the second layer 220 on the base plate 100; and a light-emitting layer 300 located on the base plate 100 and including light-emitting units 310 located in the isolation openings 240; in which a distance between orthographic projections of the first layers 210 located at two sides of a same isolation opening 240 on the base plate 100 is a sixth distance D6, and in at least two of the light-emitting units 310, the sixth distance D6 of the isolation structure 200 close to one of the two light-emitting units 310 is greater than the sixth distance D6 of the isolation structure 200 close to the other one of the two light-emitting units 310.

The display panel 10 according to the embodiments of the present application includes the base plate 100, the isolation structures 200, and the light-emitting layer 300. The first layer 210 and the second layer 220 are arranged to form the isolation structure 200, the orthographic projection of the first layer 210 arranged close to the base plate 100 on the base plate 100 is located within the orthographic projection of the second layer 220 on the base plate 100, the area of the second layer 220 is greater than the area of the first layer 210, the second layer 200 covers a surface of the first layer 210 close to the second layer 220, and in such cases, the first layer 210 is recessed with respect to the second layer 220 in a direction away from the isolation opening 240. When the light-emitting layer 300 is prepared, the light-emitting layer 300 has a large drop at the edge of the isolation structure 200, and the first layer 210 is concave with respect to the second layer 220, it's difficult for the light-emitting layer 300 to be connected at the edge of the isolation structure 200, and thus fracture occurs and the light-emitting layer 300 is fractured, resulting in the light-emitting units 310 that are spaced apart from each other. In this way, the crosstalk of carriers within the light-emitting layer 300 is reduced, the display effect of the display panel 10 is improved, and the light-emitting units 310 can be prepared without a precision mask plate, so as to reduce the development and use of the precision mask plate and reduce the preparation cost.

For example, the light-emitting units 310 include a blue light-emitting unit, a green light-emitting unit, and a red light-emitting unit, the sixth distance D6 of the isolation structure 200 close to the blue light-emitting unit is greater than the sixth distance D6 of the isolation structure 200 close to the green light-emitting unit, and the sixth distance D6 of the isolation structure 200 close to the green light-emitting unit is greater than the sixth distance D6 of the isolation structure 200 close to the red light-emitting unit, and thus it may be determined that the red light-emitting unit is prepared first, followed by the green light-emitting unit, and finally the blue light-emitting unit.

In some optional embodiments, the sixth distances D6 close to the light-emitting units 310 of a same color are the same.

In these optional embodiments, the sixth distances D6 of the isolation structures 200 located at the periphery of the light-emitting units 310 of a same color are the same, it may be determined that the light-emitting units 310 of a same color are prepared in a same step. Moreover, the sixth distances D6 corresponding to the light-emitting units 310 of a same color are the same, and if the sixth distances D6 corresponding to at least two light-emitting units 310 are different, the colors of lights emitted by the two light-emitting units 310 are different, and the two light-emitting units 310 are vapor deposited in different steps. Therefore, the sixth distances D6 corresponding to the light-emitting units 310 of a same color being controlled to be the same facilitates determining the vapor deposition order for the light-emitting units 310 according to the sixth distances D6 corresponding to the light-emitting units 310.

In some optional embodiments, the sixth distances D6 close to the light-emitting units 310 of different colors are different.

In these optional embodiments, the sixth distances D6 of the isolation structures 200 located at the periphery of the light-emitting units 310 of different colors are different, it may be determined that the light-emitting units 310 of different colors are prepared in different steps. The sixth distances D6 corresponding to the light-emitting units 310 of a same color are the same, and the sixth distances D6 corresponding to the light-emitting units 310 of different colors are different, therefore the vapor deposition order for the light-emitting units 310 can be determined according to the sixth distances D6 corresponding to the light-emitting units 310.

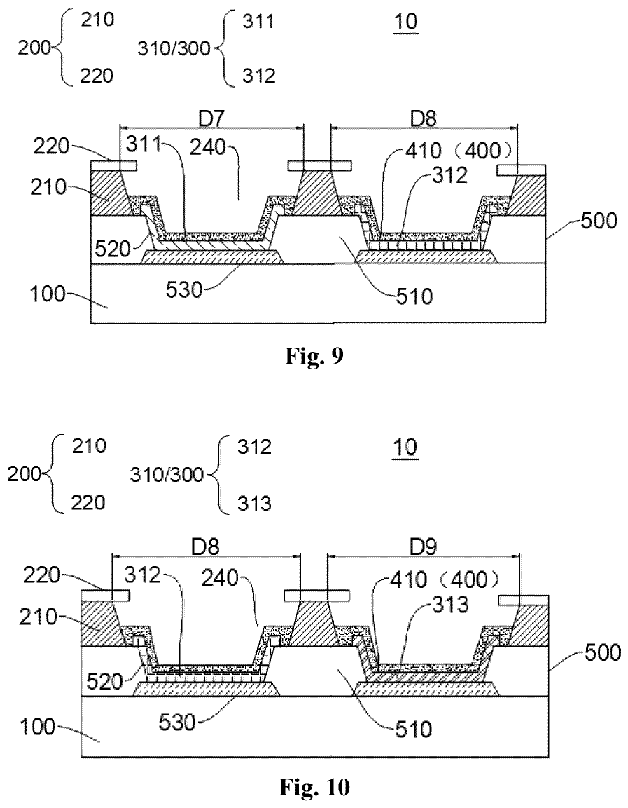

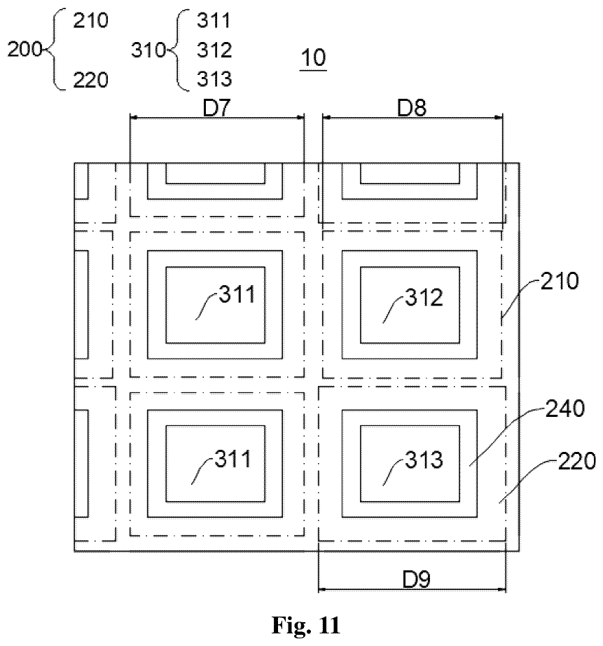

Reference is made to FIGS. 9 to 11, in which FIG. 9 shows a partial sectional view of a display panel in yet another embodiment, FIG. 10 shows a partial sectional view of a display panel in yet another embodiment, and FIG. 11 shows a partial top view of a display panel in yet another embodiment.

As shown in FIGS. 9 to 11, according to any of the above implementation of the first aspect of the present application, the light-emitting units 310 include a first light-emitting unit 311, a second light-emitting unit 312, and a third light-emitting unit 313 of different colors, the sixth distance D6 of the isolation structure 200 close to the first light-emitting unit 311 is a seventh distance D7, the sixth distance D6 of the isolation structure 200 close to the second light-emitting unit 312 is an eighth distance D8, the sixth distance D6 of the isolation structure 200 close to the third light-emitting unit 313 is a ninth distance D9, and at least two of the seventh distance D7, the eighth distance D8, and the ninth distance D9 are different.

In these optional embodiments, at least two of the seventh distance D7, the eighth distance D8, and the ninth distance D9 are different, i.e., the sixth distances D6 corresponding to at least two of the first light-emitting unit 311, the second light-emitting unit 312, and the third light-emitting unit 313 are different, and the vapor deposition order for the light-emitting units may be determined according to the different sixth distances D6. For example, the ninth distance D9 is greater than the eighth distance D8, i.e., the sixth distance D6 of the isolation structure 200 close to the third light-emitting unit 313 is greater than the sixth distance D6 of the isolation structure 200 close to the second light-emitting unit 312, it may be determined that the second light-emitting unit 312 is prepared first, followed by the third light-emitting unit 313; the eighth distance D8 is greater than the seventh distance D7, i.e., the sixth distance D6 of the isolation structure 200 close to the second light-emitting unit 312 is greater than the sixth distance D6 of the isolation structure 200 close to the first light-emitting unit 311, it may be determined that the first light-emitting unit 311 is prepared first, followed by the second light-emitting unit 312. The structural designs in the embodiment may be applied to other display panels 10 and selected according to actual situation, which is not limited herein.

The embodiments of the fourth aspect of the present application further provide a display apparatus including the display panel 10 of any of the above embodiments. Since the display apparatus according to the embodiments of the fourth aspect of the present application includes the display panel 10 of any of the above embodiments, the display apparatus has the same beneficial effects as those of the display panel 10, which will not be repeated herein.

The display apparatus in the embodiments of the present application includes, but is not limited to, a cellular phone, a Personal Digital Assistant (PDA), a tablet computer, an e-book, a television, an entrance guard, a smart fixed-line telephone, a console, and other apparatus with display function.

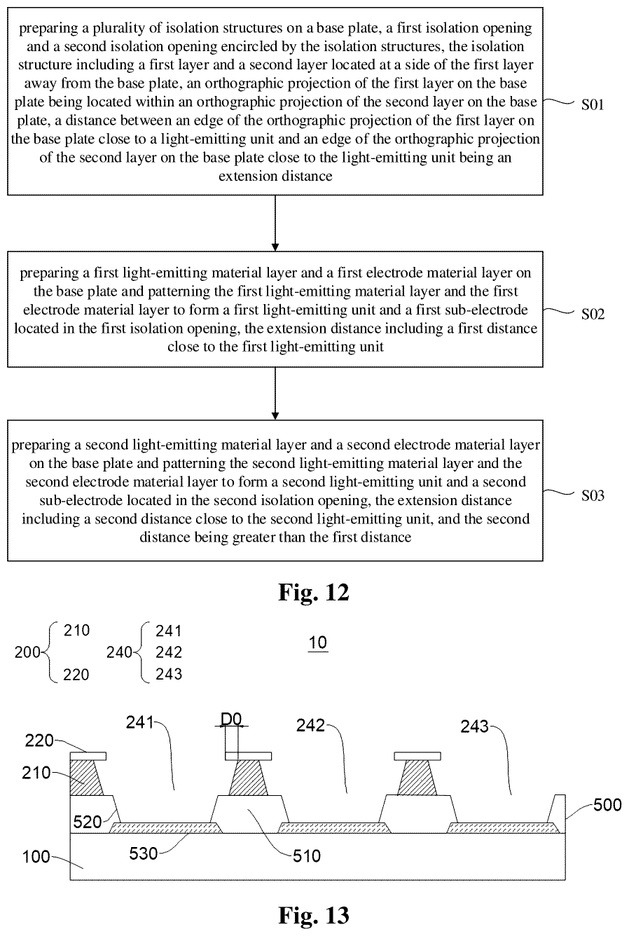

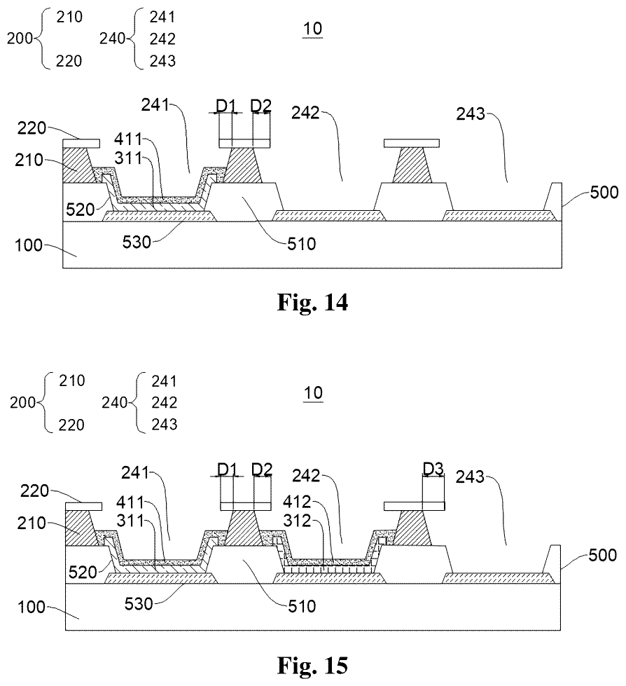

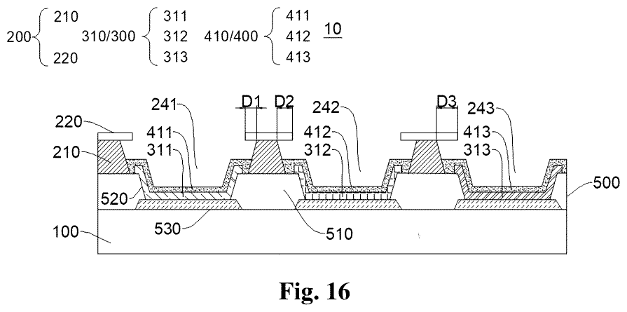

The embodiments of the fifth aspect of the present application further provide a method for manufacturing a display panel 10, which may be the display panel 10 according to any of the above embodiments of the first aspect. Reference is made to FIGS. 12 to 16, as well as FIGS. 1 to 11, in which FIG. 12 shows a schematic flow chart of a method for manufacturing a display panel according to an embodiment of the present application, and FIGS. 13 to 16 show diagrams of a process for manufacturing a display panel according to an embodiment of the present application. The method includes the following steps:
step S01: preparing a plurality of isolation structures on a base plate, a first isolation opening and a second isolation opening encircled by the isolation structures, the isolation structure including a first layer and a second layer located at a side of the first layer away from the base plate, an orthographic projection of the first layer on the base plate being located within an orthographic projection of the second layer on the base plate, a distance between an edge of the orthographic projection of the first layer on the base plate close to a light-emitting unit and an edge of the orthographic projection of the second layer on the base plate close to the light-emitting unit being an extension distance;
step S02: preparing a first light-emitting material layer and a first electrode material layer on the base plate and patterning the first light-emitting material layer and the first electrode material layer to form a first light-emitting unit and a first sub-electrode located in the first isolation opening, the extension distance including a first distance close to the first light-emitting unit;
step S03: preparing a second light-emitting material layer and a second electrode material layer on the base plate and patterning the second light-emitting material layer and the second electrode material layer to form a second light-emitting unit and a second sub-electrode located in the second isolation opening, the extension distance including a second distance close to the second light-emitting unit, and the second distance being greater than the first distance.

In the method according to the embodiments of the fifth aspect of the present application, as shown in FIG. 7, the isolation structure 200 is prepared in step S01, the first layer 210 and the second layer 220 are arranged to form the isolation structure 200, and the distance between the edge of the orthographic projection of the first layer 210 on the base plate 100 close to a light-emitting unit 310 and the edge of the orthographic projection of the second layer 220 on the base plate 100 close to the light-emitting unit 310 is used as the extension distance D0 of the isolation structure 200. As shown in FIG. 8, the first light-emitting material layer and the first electrode 410 material layer are prepared in step S02, and portions of the first light-emitting material layer and the first electrode 410 material layer located outside the first isolation opening 241 are etched, so as to obtain the first light-emitting unit 311 and the first sub-electrode 411 located in the first isolation opening 241. As shown in FIG. 9, the second light-emitting material layer and the second electrode material layer are prepared in step S03, and portions of the second light-emitting material layer and the second electrode material layer located outside the second isolation opening 242 are etched, so as to obtain the second light-emitting unit 312 and the second sub-electrode 412 located in the second isolation opening 242. When the first electrode 410 material layer is etched, the first layer 210 of the isolation structure 200 at the periphery of the second isolation opening 242 is also etched, so that the second distance D2 is greater than the first distance D1, i.e., the extension distance D0 of the isolation structure 200 close to the second light-emitting unit 312 is greater than the extension distance DO of the isolation structure 200 close to the first light-emitting unit 311. According to the first distance D1 and the second distance D2 which are different, the vapor deposition order for the first light-emitting unit 311 and the second light-emitting unit 312 may be determined.

As shown in FIG. 10, in some optional embodiments, the isolation structures 200 further encircle a third isolation opening 243, the method further includes, after step S03: preparing a third light-emitting material layer and a third electrode material layer on the base plate 100 and patterning the third light-emitting material layer and the third electrode material layer to form a third light-emitting unit 313 and a third sub-electrode 413 located in the third isolation opening 243, the extension distance D0 including a third distance D3 close to the third light-emitting unit 313, and the third distance D3 being greater than the second distance D2.

In these optional embodiments, the third light-emitting material layer and the third electrode material layer are prepared, and portions of the third light-emitting material layer and the third electrode material layer located outside the third isolation opening 243 are etched, so as to obtain the third light-emitting unit 313 and the third sub-electrode 413 located in the third isolation opening 243. When the second electrode material layer is etched, the first layer 210 of the isolation structure 200 at the periphery of the third isolation opening 243 is also etched, so that the third distance D3 is greater than the second distance D2, i.e., the extension distance DO of the isolation structure 200 close to the third light-emitting unit 313 is greater than the extension distance D0 of the isolation structure 200 close to the second light-emitting unit 312. According to the second distance D2 and the third distance D3 which are different, the vapor deposition order for the second light-emitting unit 312 and the third light-emitting unit 313 may be determined.

Optionally, in the step of preparing the isolation structures 200 on the base plate 100, the extension distances D0 towards the first isolation opening 241, the second isolation opening 242, and the third isolation opening 243 are all the same, and before preparing the light-emitting units 310, it is ensured that the extension distances D0 corresponding to the isolation openings 240 are the same, so that when the extension distances D0 corresponding to the isolation openings 240 differ from each other in a subsequent process, the vapor deposition order for the light-emitting units 310 may be determined according to the difference of the extension distances DO.

The above embodiments of the present application do not exhaustively describe all the details, nor do they limit the present application to the specific embodiments as described. Obviously, according to the above description, many modifications and changes can be made. These embodiments are selected and particularly described in the specification to better explain the principles and practical applications of the present application, so that a person skilled in the art is able to utilize the present application and make modifications based on the present application. The present application is limited only by the claims and the full scope and equivalents of the claims.

What is claimed is:

1. A display panel, comprising:
a base plate;
a plurality of isolation structures located on the base plate, the isolation structure comprising a first layer and a second layer located at a side of the first layer away from the base plate, an orthographic projection of the first layer on the base plate being located within an orthographic projection of the second layer on the base plate;
a plurality of isolation openings encircled by the isolation structures; and
a light-emitting layer located on the base plate and comprising light-emitting units located in the isolation openings;
wherein a distance between an edge of the orthographic projection of the first layer on the base plate close to the light-emitting unit and an edge of the orthographic projection of the second layer on the base plate close to the light-emitting unit is an extension distance, and in at least two of the light-emitting units, the extension distance of the isolation structure close to one of the two light-emitting units is greater than the extension distance of the isolation structure close to the other one of the two light-emitting units.

2. The display panel according to claim 1, wherein the extension distances close to the light-emitting units of a same color are same;
the extension distances close to the light-emitting units of different colors are different.

3. The display panel according to claim 1, wherein the first layer comprises a top surface at a side away from the base plate, the second layer comprises a bottom surface at a side close to the base plate, the top surface and the bottom surface are in contact, a distance between an edge of an orthographic projection of the top surface on the base plate close to the light-emitting unit and an edge of an orthographic projection of the bottom surface on the base plate close to the light-emitting unit is the extension distance.

4. The display panel according to claim 1, wherein the light-emitting units comprise a first light-emitting unit, a second light-emitting unit, and a third light-emitting unit of different colors, the extension distance of the isolation structure close to the first light-emitting unit is a first distance, the extension distance of the isolation structure close to the second light-emitting unit is a second distance, the extension distance of the isolation structure close to the third light-emitting unit is a third distance, and at least two of the first distance, the second distance, and the third distance are different.

5. The display panel according to claim 1, wherein
the third distance is greater than the second distance;
the second distance is greater than the first distance; and
the first light-emitting unit is a light-emitting unit emitting red light, the second light-emitting unit is a light-emitting unit emitting green light, and the third light-emitting unit is a light-emitting unit emitting blue light.

6. The display panel according to claim 1, wherein the extension distance is in a range of 0.1 μm to 1.5 μm.

7. The display panel according to claim 1, wherein
the display panel further comprises a pixel defining layer located on the base plate, the pixel defining layer comprises a plurality of pixel defining portions and a plurality of pixel openings encircled by the pixel defining portions, the pixel opening is communicated with the isolation opening;
the isolation structure is located at a side of the pixel defining portion away from the base plate.

8. The display panel according to claim 7, wherein the display panel further comprises a plurality of pixel electrodes located at a side of the pixel defining portions close to the base plate, an orthographic projection of the pixel electrode on the base plate at least partially overlaps an orthographic projection of the pixel opening on the base plate.

9. The display panel according to claim 7, wherein a distance between the edge of the orthographic projection of the first layer on the base plate close to the light-emitting unit and an edge of the orthographic projection of the pixel opening on the base plate is a fourth distance, and in at least two of the light-emitting units, the fourth distance of the isolation structure close to one of the two light-emitting units is greater than the fourth distance of the isolation structure close to the other one of the two light-emitting units; and
the fourth distances close to the light-emitting units of a same color are the same, and the fourth distances close to the light-emitting units of different colors are different.

10. The display panel according to claim 1, wherein
the display panel further comprises a first electrode layer located a side of the light-emitting layer away from the base plate;
the first electrode layer comprises a plurality of first electrodes arranged at intervals, the first electrode is electrically connected with the isolation structure;
an orthographic projection of the light-emitting unit on the base plate is located within an orthographic projection of the first electrode on the base plate.

11. The display panel according to claim 1, wherein the light-emitting units and the isolation structures are arranged alternately;
the second layer comprises an electrically conductive material or an electrically insulating material.

12. The display panel according to claim 1, wherein the second layer comprises a metal material, the first layer and the second layer are of different materials.

13. The display panel according to claim 1, wherein the isolation structure further comprises a third layer located at a side of the first layer towards the base plate, the orthographic projection of the first layer on the base plate is located within an orthographic projection of the third layer on the base plate;
a distance between an edge of the orthographic projection of the third layer on the base plate close to the light-emitting unit and the edge of the orthographic projection of the second layer on the base plate close to the light-emitting unit is a fifth distance, and in at least two of the light-emitting units, the fifth distance of the isolation structure close to one of the two light-emitting units is greater than the fifth distance of the isolation structure close to the other one of the two light-emitting units; and
the fifth distances close to the light-emitting units of a same color are same.

14. A display panel, comprising:
a base plate;
a plurality of isolation structures located on the base plate the isolation structure comprising a first layer and a second layer located at a side of the first layer away from the base plate, an orthographic projection of the first layer on the base plate being located within an orthographic projection of the second layer on the base plate;
a plurality of isolation openings encircled by the isolation structures; and
a light-emitting layer located on the base plate and comprising light-emitting units located in the isolation openings;
wherein the first layer comprises a top surface at a side away from the base plate, the second layer comprises a bottom surface at a side close to the base plate, the top surface and the bottom surface are in contact, a distance between an edge of an orthographic projection of the top surface on the base plate close to the light-emitting unit and an edge of an orthographic projection of the bottom surface on the base plate close to the light-emitting unit is an extension distance, and in at least two of the light-emitting units, the extension distance of the isolation structure close to one of the two light-emitting units is greater than the extension distance of the isolation structure close to the other one of the two light-emitting units,
wherein the extension distances close to the light-emitting units of a same color are same; and
the extension distances close to the light-emitting units of different colors are different.

15. The display panel according to claim 14, wherein the light-emitting units comprise a first light-emitting unit, a second light-emitting unit, and a third light-emitting unit of different colors, the extension distance of the isolation structure close to the first light-emitting unit is a first distance, the extension distance of the isolation structure close to the second light-emitting unit is a second distance, the extension distance of the isolation structure close to the third light-emitting unit is a third distance, and at least two of the first distance, the second distance, and the third distance are different;
the third distance is greater than the second distance;
the second distance is greater than the first distance; and
the first light-emitting unit is a light-emitting unit emitting red light, the second light-emitting unit is a light-emitting unit emitting green light, and the third light-emitting unit is a light-emitting unit emitting blue light.

16. A display panel, comprising:
a base plate;
a plurality of isolation structures located on the base plate, the isolation structure comprising a first layer and a second layer located at a side of the first layer away from the base plate, an orthographic projection of the first layer on the base plate being located within an orthographic projection of the second layer on the base plate;
a plurality of isolation openings encircled by the isolation structures; and
a light-emitting layer located on the base plate and comprising light-emitting units located in the isolation openings;
wherein a distance between orthographic projections of the first layers located at two sides of a same isolation opening on the base plate is a sixth distance, and in at least two of the light-emitting units, the sixth distance of the isolation structure close to one of the two light-emitting units is greater than the sixth distance of the isolation structure close to the other one of the two light-emitting units.

17. The display panel according to claim 16, wherein the sixth distances close to the light-emitting units of a same color are same; and
the sixth distances close to the light-emitting units of different colors are different.

18. The display panel according to claim 16, wherein the light-emitting units comprise a first light-emitting unit, a second light-emitting unit, and a third light-emitting unit of different colors, the sixth distance of the isolation structure close to the first light-emitting unit is a seventh distance, the sixth distance of the isolation structure close to the second light-emitting unit is an eighth distance, the sixth distance of the isolation structure close to the third light-emitting unit is a ninth distance, and at least two of the seventh distance, the eighth distance, and the ninth distance are different;
the ninth distance is greater than the eighth distance;
the eighth distance is greater than the seventh distance; and
the first light-emitting unit is a light-emitting unit emitting red light, the second light-emitting unit is a light-emitting unit emitting green light, and the third light-emitting unit is a light-emitting unit emitting blue light.

19. A method for manufacturing a display panel, comprising:
preparing a plurality of isolation structures on a base plate, a first isolation opening and a second isolation opening encircled by the isolation structures, the isolation structure comprising a first layer and a second layer located at a side of the first layer away from the base plate, an orthographic projection of the first layer on the base plate being located within an orthographic projection of the second layer on the base plate, a distance between an edge of the orthographic projection of the first layer on the base plate close to a light-emitting unit and an edge of the orthographic projection of the second layer on the base plate close to the light-emitting unit being an extension distance;
preparing a first light-emitting material layer and a first electrode material layer on the base plate and patterning the first light-emitting material layer and the first electrode material layer to form a first light-emitting unit and a first sub-electrode located in the first isolation opening, the extension distance comprising a first distance close to the first light-emitting unit; and
preparing a second light-emitting material layer and a second electrode material layer on the base plate and patterning the second light-emitting material layer and the second electrode material layer to form a second light-emitting unit and a second sub-electrode located in the second isolation opening, the extension distance comprising a second distance close to the second light-emitting unit, and the second distance being greater than the first distance.

20. The according to claim 19, wherein the isolation structures further encircle a third isolation opening,
the method further comprises, after forming the second light-emitting unit and the second sub-electrode located in the second isolation opening:
preparing a third light-emitting material layer and a third electrode material layer on the base plate and patterning the third light-emitting material layer and the third electrode material layer to form a third light-emitting unit and a third sub-electrode located in the third isolation opening, the extension distance comprising a third distance close to the third light-emitting unit, and the third distance being greater than the second distance.

21. The according to claim 19, wherein in preparing the isolation structures on the base plate, the extension distances towards the first isolation opening, the second isolation opening, and the third isolation opening are all the same.

22. The according to claim 19, wherein the first light-emitting unit is a light-emitting unit emitting red light, the second light-emitting unit is a light-emitting unit emitting green light, and the third light-emitting unit is a light-emitting unit emitting blue light.
